(19) United States
(12) Patent Application Publication
(10) Pub. No.: US 2002/0068465 A1
(43) Pub. Date: Jun. 6, 2002

(54) Method of producing an oxidation-protected electrode for a capacitive electrode structure

(76) Inventors: Anke Krasemann, Dresden (DE); Thomas Pompl, Altdorf (DE); Martin Schrems, Langebruck (DE); Helmut Wurzer, Dresden (DE)

Correspondence Address: LERNER AND GREENBERG, P.A., POST OFFICE BOX 2480, HOLLYWOOD, FL, 33022-2480, US

(21) Appl. No.: 09/729,058

(22) Filed: Dec. 4, 2000

(30) Foreign Application Priority Data
Dec. 2, 1999 (DE) 199 58 203.3

(51) Int. Cl. H01L 21/336; H01L 21/31; H01L 21/469

(52) U.S. Cl. 438/763

(57) ABSTRACT

The capacitive electrode structure has a semiconductor substrate, a metal oxide layer on the semiconductor substrate, an oxidation inhibiting layer on the metal oxide layer, and an electrode formed on the oxidation inhibiting layer. The oxidation inhibiting layer is substantially impervious to oxygen and prevents oxygen atoms from diffusing into the metal oxide layer.

### BACKGROUND OF THE INVENTION

1. Field of the Invention

The invention relates to a method for producing an oxidation-protected electrode for a capacitive electrode structure, and to a capacitive electrode structure in which the electrode is protected against oxidation by oxygen atoms which are present in an oxygen-enriched metal oxide layer underneath the electrode.

Capacitive electrode structures are widespread and are used in particular for the capacitive driving of MOS transistors and in volatile memories, for example DRAM.

MOS transistors have a control electrode or a gate terminal which, by virtue of a gate dielectric, is remote from the current-carrying channel in the semiconductor substrate. If a voltage is applied to the gate electrode, an electric field strength arises in the gate dielectric and causes charges on the semiconductor surface located underneath. Improved capacitive driving of MOS transistors becomes possible by reducing the layer thickness of the gate dielectric and/or by using new dielectric materials having higher dielectric constants ε_{R}.

In volatile memories, for example DRAM (dynamic random access memory), the storage capacitance is decreased by reducing structure dimensions. For compensation, therefore, it is necessary to increase the capacitance per unit area or the capacitance per area of the capacitive memory electrode structures. This can likewise be achieved by reducing the thickness of the dielectric layer and/or by using dielectric materials having relatively high dielectric constants ε_{R}.

There exist a series of known dielectric materials having relatively high dielectric constants, such as, for example, tantalum pentoxide Ta₂O₅, titanium dioxide TiO₂, and aluminum oxide Al₂O₃. All these materials have a relatively high proportion of oxygen.

With reference to FIG. 1, there is shown a capacitive electrode structure according to the prior art.

A metal barrier layer, for example silicon dioxide or silicon nitride, is formed on a silicon substrate. A layer of an easily oxidizing metal whose oxide has a high dielectric constant, for example titanium, tantalum, or aluminum, is deposited on the barrier layer. The metal layer is thereby generally deposited by sputtering, CVD, or MBE processes (MBE=molecular beam epitaxy). The metal layer is then thermally oxidized. In this case, the underlying barrier dielectric prevents the metal from penetrating into the silicon substrate located underneath, so that no undesirable metal-silicon compounds can be produced there. The metal barrier layer is composed of pure silicon oxide, pure silicon nitride, or a nitride silicon oxide layer. The metal oxide can also be formed by a CVD process (CVD=chemical vapor deposition) or JVD process (JVD=jet vapor deposition) instead of by thermal oxidation of a deposited metal layer.

Polysilicon is subsequently deposited on the metal oxide layer having the high dielectric constant ε_{R}. A silicon dioxide layer thereby forms between the metal oxide layer MeO and the polysilicon. The reason for this is that the underlying metal oxide layer MeO is an oxygen-rich layer having many oxygen atoms which combine with the deposited polysilicon to form silicon dioxide. The oxide layer formed on the metal oxide Me has the disadvantage that it leads to an additional capacitive load.

### Summary of the Invention

The object of the invention is to provide a production method for producing an oxidation-protected electrode for a capacitive structure, and a capacitive electrode structure, which overcomes the above-noted deficiencies and disadvantages of the prior art devices and methods of this kind, and in which the oxidation of the electrode material applied on the metal oxide layer as a result of the oxygen contained in the metal oxide layer is avoided.

With the above and other objects in view there is provided, in accordance with the invention, a method of producing an oxidation-protected electrode for a capacitive electrode structure. The method comprises the following steps:

forming a metal oxide layer on a substrate;

applying an oxidation inhibiting layer, configured to be impervious to oxygen atoms, on the metal oxide layer; and

forming an electrode on the oxidation inhibiting layer.

In other words, the invention provides for a method which includes formation of a metal oxide layer on a substrate, application of an oxidation inhibiting layer, which is impervious to oxygen atoms, on the metal oxide layer, and application of the electrode to the oxidation inhibiting layer.

In accordance with a preferred embodiment, the metal oxide layer is formed by thermal oxidation of a deposited metal layer.

Preferably, a metal barrier layer is formed with respect to the substrate prior to the application of the metal layer.

This affords the particular advantage that no disturbing metal-substrate compounds can be produced in the substrate.

In a further advantageous refinement of the method according to the invention, the oxidation inhibiting layer is applied by chemical vapor phase deposition or by a CVD process.

With the above and other objects in view there is also provided, in accordance with the invention, a capacitive electrode structure, comprising:

a semiconductor substrate;

a metal oxide layer formed on said semiconductor substrate;

an oxidation inhibiting layer on said metal oxide layer; and

an electrode on said oxidation inhibiting layer.

In accordance with another feature of the invention, the oxidation inhibiting layer is electrically conductive. This affords the particular advantage that the oxidation inhibiting layer, as an electrically conductive material, can itself serve as an electrode for connection to further electrical components.

In accordance with a further preferred development, a metal layer is formed on the electrically conductive oxidation inhibiting layer for the purpose of forming an electrode.

The electrically conductive oxidation inhibiting layer is preferably composed of tungsten nitride.

In accordance with an alternative embodiment, the oxidation inhibiting layer is composed of titanium nitride.

In accordance with a further alternative embodiment of the electrode structure according to the invention, the oxidation inhibiting layer is composed of a material that is not electrically conductive, and a polysilicon layer is applied to the oxidation inhibiting layer for the purpose of forming the electrode.

In this case, the electrically non-conductive oxidation inhibiting layer is preferably composed of a material having a high dielectric constant.

This has the advantage of reducing the load capacitance.

In a preferred embodiment, the electrically non-conductive oxidation inhibiting layer is composed of silicon nitride.

In a further preferred embodiment of the capacitive electrode structure, the metal oxide layer is composed of an oxygen-rich material having a high dielectric constant.

The metal oxide layer is composed of titanium dioxide in a first embodiment.

The metal oxide layer is composed of tantalum pentoxide in a further embodiment.

The metal oxide layer is composed of aluminum oxide in a further preferred embodiment.

In accordance with again a further preferred embodiment, a metal barrier layer is provided between the metal oxide layer and the substrate.

This affords the particular advantage that no undesired metal-substrate compounds are produced.

The metal barrier layer is preferably composed of silicon dioxide.

In an alternative embodiment, the metal barrier layer is composed of silicon nitride.

The oxidation inhibiting layer is preferably composed of a nitrogen-rich compound for preventing the diffusion of oxygen atoms through the oxidation inhibiting layer.

Other features which are considered as characteristic for the invention are set forth in the appended claims.

Although the invention is illustrated and described herein as embodied in a method for producing an oxidation-protected electrode for a capacitive electrode structure, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a partial diagrammatic side view of a prior art electrode structure; and

FIG. 2 is a similar view of a capacitive electrode structure according to the present invention.

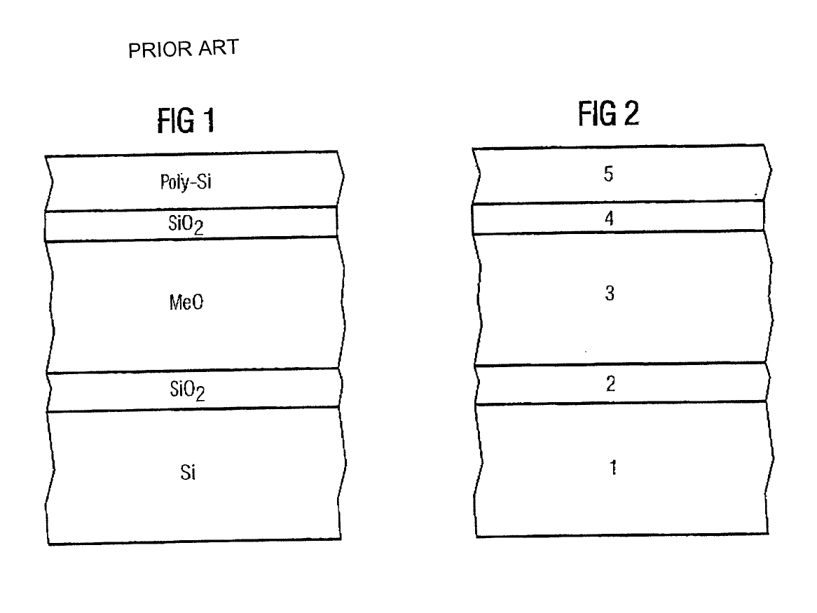

### DESCRIPTION OF THE PREFERRED EMBODIMENTS

Referring now to the drawing in detail, in the novel process for producing an oxidation-protected electrode for a capacitive electrode structure, a barrier layer 2, preferably a metal barrier layer 2, is formed on a substrate 1. The latter, in the exemplary embodiment, is a silicon substrate. The metal barrier layer 2 is therefore preferably composed of silicon dioxide or of silicon nitride. A metal oxide layer 3 is formed on the metal barrier layer 2. The metal oxide layer 3 is preferably formed by thermal oxidation of a metal layer deposited on the metal barrier layer 2. In this case, the metal layer of the strongly oxidizing metal whose oxide has a high dielectric constant such as, for example, titanium, tantalum or aluminum, is deposited on the metal barrier layer 2 by sputtering, by means of a CVD process or an MBE process.

This deposited metal layer made of titanium, tantalum or aluminum is then thermally oxidized to form titanium dioxide, tantalum pentoxide or aluminum oxide. In this case, the metal barrier layer 2 prevents metal ions from penetrating into the substrate 1, so that no undesirable metal-substrate compounds are produced there.

The metal oxide layer 3 can also be applied directly by chemical vapor phase deposition of the oxide.

In the next step, an oxidation inhibiting layer 4, which is impervious to oxygen atoms, is applied to the metal oxide layer 3 that has been produced in this way.

The oxidation inhibiting layer is composed either of a nonconductive or insulating material or of an electrically conductive material.

If the oxidation inhibiting layer 4 is electrically conductive in accordance with a first embodiment, this affords the advantage that the oxidation inhibiting layer 4 itself can form the electrically conductive electrode. In this case, in further embodiments, the electrically conductive oxidation inhibiting layer 4 can be coated with further electrically conductive metal layers in order to produce an electrode in accordance with the technological production process. An electrically conductive oxidation inhibiting layer 4 is preferably applied by means of a CVD process. In this case, the electrically conductive oxidation inhibiting layer is preferably composed of tungsten nitride or titanium nitride. The nitrogen-rich compounds prevent oxygen atoms from passing from the metal oxide layer 3 through the oxidation inhibiting layer 4.

In an alternative embodiment, the oxidation inhibiting layer 4 is composed of a material which is not electrically conductive. The electrically non-conductive material of the oxidation inhibiting layer 4 is chosen such that it has a high dielectric constant. This results in only a low load capacitance. The electrically non-conductive material of the oxidation inhibiting layer is preferably composed of silicon nitride.

The oxidation inhibiting layer 4 is then preferably coated with a polysilicon layer 5 for the purpose of forming the electrode. The oxidation inhibiting layer 4 prevents oxygen atoms from passing through from the oxygen-rich metal oxide layer 3 into the polysilicon layer 5, with the result that the polysilicon layer 5 is not oxidized. In particular, the oxidation inhibiting layer 4 prevents diffusion of oxygen atoms on account of a concentration gradient that is present into the polysilicon layer. This is preferably achieved by nitrogen contained in the oxidation inhibiting layer 4.

The capacitive electrode structure according to the invention as shown in FIG. 2 has a very high capacitance per unit area on account of the metal oxide layer 3 contained therein. The layer 3 has a very high dielectric constant ε_{R}. At the same time, the oxidation inhibiting layer 4 prevents the overlying polysilicon layer from being oxidized by the oxygen-rich metal oxide layer 3. The capacitive electrode structure shown in FIG. 2 is outstandingly suitable for the miniaturization of a multilayer dielectric, for example in volatile memories, such as DRAM or MOS structures. At the same time, the technological production process can readily be controlled on account of the particular materials used, so that there are very few rejects during the production of such capacitive electrode structures. In the case of a conductive oxidation inhibiting layer 4, such as, for example, tungsten nitride, the electrode, for example the gate electrode, can be integrated, resulting in independence from polysilicon gate depletion effects.

We claim:

1. A method of producing an oxidation-protected electrode for a capacitive electrode structure, which comprises the following steps:
forming a metal oxide layer on a substrate;
applying an oxidation inhibiting layer, configured to be impervious to oxygen atoms, on the metal oxide layer; and
forming an electrode on the oxidation inhibiting layer.

2. The method according to claim 1, wherein the step of forming the metal oxide layer comprises thermally oxidizing a deposited metal layer.

3. The method according to claim 1, which comprises forming a metal barrier layer between the metal oxide layer and the substrate.

4. The method according to claim 1, wherein the applying step comprises forming the oxidation inhibiting layer by chemical vapor phase deposition.

5. A capacitive electrode structure, comprising:
a semiconductor substrate;
a metal oxide layer formed on said semiconductor substrate;
an oxidation inhibiting layer on said metal oxide layer; and
an electrode on said oxidation inhibiting layer.

6. The capacitive electrode structure according to claim 5, wherein said oxidation inhibiting layer is electrically conductive.

7. The capacitive electrode structure according to claim 6, wherein said electrode is formed by a metal layer on said electrically conductive oxidation inhibiting layer.

8. The capacitive electrode structure according to claim 6, wherein said electrically conductive oxidation inhibiting layer is composed of tungsten nitride.

9. The capacitive electrode structure according to claim 6, wherein said electrically conductive oxidation inhibiting layer is composed of titanium nitride.

10. The capacitive electrode structure according to claim 5, wherein said oxidation inhibiting layer is not electrically conductive and said electrode is formed by a polysilicon layer on said oxidation inhibiting layer.

11. The capacitive electrode structure according to claim 10, wherein said electrically non-conductive oxidation inhibiting layer is composed of a material having a high dielectric constant.

12. The capacitive electrode structure according to claim 10, wherein said electrically non-conductive oxidation inhibiting layer is composed of silicon nitride.

13. The capacitive electrode structure according to claim 5, wherein said metal oxide layer is composed of an oxygen-rich material having a high dielectric constant.

14. The capacitive electrode structure according to claim 13, wherein said metal oxide layer is composed of titanium dioxide.

15. The capacitive electrode structure according to claim 13, wherein said metal oxide layer is composed of tantalum pentoxide.

16. The capacitive electrode structure according to claim 13, wherein said metal oxide layer is composed of aluminum oxide.

17. The capacitive electrode structure according to claim 5, which comprises a metal barrier layer between said metal oxide layer and said substrate.

18. The capacitive electrode structure according to claim 17, wherein said metal barrier layer is composed of silicon dioxide.

19. The capacitive electrode structure according to claim 17, wherein said metal barrier layer is composed of silicon nitride.

20. The capacitive electrode structure according to claim 5, wherein said oxidation inhibiting layer comprises a nitrogen-rich compound for preventing a diffusion of oxygen atoms through said oxidation inhibiting layer.
